(19) United States
(12) Patent Application Publication
(10) Pub. No.: US 2025/0189384 A1
(43) Pub. Date: Jun. 12, 2025

(54) Sensor for sensing temperature and measuring the state of charge (SOC) of a fiber-optic accumulator comprising one or more thermoluminescent materials, at one or more emission peaks in a region of variation of the optical absorption spectrum of the insertion material of an electrode

(71) Applicant: COMMISSARIAT A L'ENERGIE ATOMIQUE ET AUX ENERGIES ALTERNATIVES, Paris (FR)

(72) Inventor: Olivier RACCURT, Grenoble Cedex (FR)

(21) Appl. No.: 18/978,830

(22) Filed: Dec. 12, 2024

(30) Foreign Application Priority Data
Dec. 12, 2023 (FR) 2314028

(51) Int. Cl. G01K 11/32; G01R 31/374; G01R 31/378; G01R 31/382; H01M 10/0525; H01M 10/48

(52) U.S. Cl. CPC G01K 11/32; G01R 31/374; G01R 31/378; G01R 31/382; H01M 10/0525; H01M 10/486

(57) ABSTRACT

Sensor for sensing temperature and measuring the state of charge (SOC) of a fiber-optic accumulator comprising one or more thermoluminescent materials, at one or more emission peaks in a region of variation of the optical absorption spectrum of the insertion material of an electrode. A sensor for sensing temperature and measuring the state of charge (SOC) of a metal-ion accumulator, including an optical fiber one free end of which forms an optical probe including one or more thermoluminescent materials capable of emitting a light peak at at least two wavelengths, at least one of the two peaks being designed to be in at least one region of variation of the optical absorption spectrum of the metal ion insertion material of at least one electrode of the accumulator, the ratio of the two peaks depending on the temperature of the accumulator and the variation in intensity of at least one of the two peaks being dependent on the insertion of the metal ions into the electrode.

### TECHNICAL FIELD

The present invention relates to the field of instrumentation, in particular of sensors for measuring an operating parameter of an accumulator or battery.

It relates more particularly to fiber-optic sensors designed for such a measurement.

The invention aims to propose a solution for estimating both the temperature and the state of charge of a battery, based on a single fiber-optic sensor.

The invention is described with reference to use for carrying out measurements within electrochemical accumulators or batteries, in particular metal-ion accumulators or batteries, in order to estimate as quickly as possible the temperature and at the same time the operating parameter known as state of charge (SOC).

Although it is described with reference to a lithium-ion accumulator, the invention is applicable to measuring the temperature of any metal-ion electrochemical accumulator, that is to say also sodium-ion, magnesium-ion, aluminum-ion, etc. accumulators, or more generally to any electrochemical accumulator whose anode or cathode material has an optical absorption that changes with its state of charge.

In general, a sensor according to the invention may be implemented in any industrial, medical or biological application that, at one time or another, requires the determination of a temperature, in particular in a range from −180° C. to 400° C.

The term “thermoluminescence” is understood here and within the scope of the invention to mean the ability of a material to emit, almost instantaneously, at a given temperature and under the effect of light radiation referred to as absorption or excitation radiation, light radiation of the same wavelength or of a different wavelength, referred to as emission radiation.

The light radiation emitted by the thermoluminescent material is characterized by an emission spectrum comprising one or more peaks whose luminescence intensity and/or lifetime varies as a function of the temperature to which the material is subjected.

### BACKGROUND

As illustrated schematically in FIGS. 1 and 2, a lithium-ion battery or accumulator usually comprises at least one electrochemical cell consisting of an electrolyte constituent 1 between a positive electrode or cathode 2 and a negative electrode or anode 3, a current collector 4 connected to the cathode 2, a current collector 5 connected to the anode 3 and lastly a packaging 6 designed to contain in a sealtight manner the electrochemical cell while at the same time being passed through by a portion of the current collectors 4, 5.

The architecture of conventional lithium-ion batteries comprises an anode, a cathode and an electrolyte. Several types of conventional architecture geometry are known:
a cylindrical geometry as disclosed in patent application US2006/0121348,
a prismatic geometry as disclosed in patents U.S. Pat. Nos. 7,348,098 and 7,338,733;
a stacked geometry as disclosed in patent applications US 2008/060189, US 2008/0057392, and patent U.S. Pat. No. 7,335,448.

The electrolyte constituent 1 may be in solid, liquid or gel form. In the latter form, the constituent may comprise a separator made of polymer, of ceramic or of microporous composite impregnated with organic or ionic liquid electrolyte(s), which enables lithium ions to move from the cathode to the anode for charging and vice versa for discharging, this generating current. The electrolyte is generally a mixture of organic solvents, for example carbonates, to which is added a lithium salt, typically LiPF6.

The positive electrode or cathode 2 consists of lithium cation insertion materials that are generally composite, such as lithium-iron-phosphate (LiFePO₄ or LFP), LiCoO₂, nickel-manganese-cobalt (NMC), including LiNi_{0.33}Mn_{0.33}Co_{0.33}O₂, or even nickel-cobalt-aluminum (NCA).

The negative electrode or anode 3 very often consists of carbon graphite or of Li₄TiO₅O₁₂ (titanate material), possibly also based on silicon or a composite formed on a silicon basis. The current collector 4 connected to the positive electrode is generally made of aluminum.

The current collector 5 connected to the negative electrode is generally made of copper, of nickel-plated copper or of aluminum.

A lithium-ion battery or accumulator may of course comprise a plurality of electrochemical cells stacked on top of one another.

Traditionally, a Li-ion battery or accumulator uses a pair of materials at the anode and at the cathode that enable it to operate at a high voltage level, typically equal to 3.6 volts.

It is essential to be able to measure a certain number of parameters of a lithium-ion accumulator in real time in order to optimize its operation, its performance, its safety and its ageing.

A BMS (battery management system) is used at the level of one accumulator or one set of accumulators in the case of a module or a battery pack, in order to protect the elements from factors that increase their hazardousness, such as excessively high currents, unsuitable potentials (excessively high or excessively low) and limit temperatures, and therefore has the role in particular of stopping current applications as soon as threshold voltage values are reached, that is to say a potential difference between the two active insertion materials.

The BMS therefore stops current applications (charging, discharging) as soon as threshold voltages (difference in potentials of the two active materials) are reached. However, the potentials of the active materials, which are not able to be measured by the BMS, no longer reach the threshold values of the extreme initial states of charge of the accumulator (0 and 100%) owing to the lack of lithium ions able to be exchanged. Current applications are not stopped early enough in extreme states of charge, thereby also leading to overvoltages on the active materials, leading to structural and chemical degradation thereof.

In order to be able to operate optimally, a BMS requires real-time measurements of physical parameters such as voltage, current and temperature.

However, the tendency is to increase the number of quantities to be measured in order to improve the performance of the BMS. Mention may be made for example of the European Battery2030+ roadmap, which has been enacted in this context: [1].

At present, it is difficult to access a certain number of internal parameters of an accumulator, such as temperature and potential of the electrodes, using external measurements.

For this reason, many works, in particular the ISNTABAT project: [2], relate to the development of sensors able to be installed within an accumulator.

Fiber-optic sensors have numerous advantages, including that of being able to be miniaturized, and therefore of being able to be installed in an environment that is constrained in terms of available space. In addition, they are electrically non-conductive and make it possible to utilize the properties of light to probe various physical or chemical parameters within an element, in particular an accumulator or battery: [3], [4], [5].

Among these parameters, the temperature of an accumulator and the state of lithiation of an electrode have already been probed with fiber-optic sensors.

Existing thermoluminescent particle-based fiber-optic sensors implement an emission peak ratiometry-based thermoluminescence principle.

According to this principle, a luminescent material has an emission spectrum comprising multiple peaks at distinct wavelengths, at least one of which has an intensity that varies with temperature, while others will remain constant.

FIG. 3 illustrates the luminescence spectrum of a thermoluminescent particle-based fiber-optic sensor whose two emission peaks change as a function of the temperature to which they are subjected.

If a constant peak and a temperature-dependent peak are chosen from among the peaks exhibiting thermal coupling, then the temperature measurement may be found by way of the luminescence measurement using the relationship according to equation 1, as follows:

$$ln ( FIR ) = - \frac{Δ E}{{k}_{B}} ( \frac{1}{T} ) + ln ( B ) \qquad [ Equation 1 ]$$

in which
   FIR is the ratio of intensity (or integrals) of the two emission peaks,
   T is temperature,
   k_{B} is the Boltzmann constant,
   ΔE is the energy difference between the two energy levels corresponding to the two luminescence peaks, and which are thermally coupled,
   B is a constant.

Plotting the ratio of the intensities of the two peaks as a function of the inverse of the temperature gives rise to a straight line with a slope

$$- \frac{Δ E}{{k}_{B}} ,$$

which is a constant dependent solely on the luminescent probe used.

This logarithmic response of the sensor according to FIG. 3 is illustrated in FIG. 4.

One conventional implementation of a thermoluminescent particle-based fiber-optic sensor consists in producing a probe based on said particles deposited at one end of an optical fiber and/or on sites over the length of an optical fiber using a sol-gel process.

During operation, absorption or excitation light radiation is sent through the optical fiber so as to reach the probe. The resulting emission radiation is recovered and returned by the same fiber to a detector (a photodiode, photomultiplier, spectrophotometer, etc.) that makes it possible to measure the fluorescence signal and therefore to measure the temperature through signal processing.

One example of this type of fiber-optic sensor is described in patent application EP 4155700A1.

The inventors carried out temperature measurement tests during cycling of a Li-ion accumulator comprising a liquid electrolyte impregnated in a conventional separator, by way of such a sensor, by positioning it between the NMC (nickel-manganese-cobalt) positive electrode and the separator.

FIG. 5 illustrates the variation in the intensity of the luminescence signal of the sensor and the external temperature of the Li-ion accumulator of 1 A·h during cycling (charging and discharging). The curves that are indicated are respectively, from top to bottom, the variation in the voltage, the variation in the applied current of the accumulator, the temperature Tₑₓₜ measured by thermocouple, and spectral intensity as a function of time over a wavelength range centered on the second luminescence peak, which decreases when the temperature increases.

FIG. 6 illustrates, on the two curves at the bottom, the variation in the internal temperature Tᵢₙₜ, therefore measured with a sensor according to patent application EP4155700A1, compared with the variation in the external temperature Tₑₓₜ as a function of the cycling to which the accumulator is subjected.

It may be seen that these two curves are almost identical, thereby indicating that the sensor is reliable and accurate.

One of the noteworthy properties of graphite is that its color, in other words its optical absorption, depends on its state of lithiation. This property is already utilized in particular to carry out measurement of the state of lithiation of graphite in the context of post-mortem or ex-situ analysis of a battery.

Based on this observation, researchers have developed a fiber-optic sensor to monitor the change in color of a graphite negative electrode within an accumulator, and therefore its state of lithiation, based on an optical fiber. There have been many publications regarding these works: [6], [7], [8], [9], [10].

The sensor that is implemented and its operation may be summarized as follows:
the optical fiber is prepared so as to create a region for generating a surface evanescent wave. For this purpose, the sheath of the fiber is removed over a distance of the order of 1 cm. This evanescent wave is used to probe the surface of the graphite negative electrode,
the optical fiber is placed in the accumulator so as to be in contact with the surface of the negative electrode or else inserted into the thickness thereof (see figures in publications [6] and for one example of the installation of the optical fiber),
the state of lithiation is estimated by injecting light, which may either have a wide spectral band, for example generated by a xenon lamp, or be one or more narrowband light sources, in particular white light, generated by LED sources, and then by quantifying the light transmitted through the fiber and the optical absorption at the portion of the fiber generating the evanescent wave. Indeed, since graphite changes color as a function of its state of lithiation, the same applies with regard to its optical absorption.

Such a sensor therefore makes it possible to measure the state of lithiation of a graphite negative electrode and to carry out in situ (in operando) monitoring of the accumulator.

The works also showed that the optical absorption spectrum of graphite varies over a relatively wide spectral band.

One illustration of these works is reproduced in FIGS. 7, 8 and 9.

These figures show, respectively:
the variation in the color of graphite as a function of its state of lithiation (levels II, III and IV) and the state of charge of the electrode between 40 and 80%;
a variation in the reflectance spectrum of graphite as a function of state of charge in a wavelength range between 500 and 900 nm, measured by reflectance on a negative electrode alone (post mortem),
a variation in the transmittance spectrum (ΔT/T) as a function of the state of charge (capacity) of an accumulator, measured in-situ by way of evanescent waves using an optical fiber.

The evanescent wave technique that has just been described has many drawbacks, including:
the need to use a wideband light source or else LEDs of suitable wavelength,
a constraint of having to install the optical fiber, which means that it has to pass through either side of the accumulator. However, the passage between the inside and the outside of an accumulator is always critical, since it is necessary to guarantee long-term sealtightness over the entire specified lifetime of the accumulator,
the passage constitutes a point of mechanical weakness of the optical fiber.

There are thus multiple fiber-optic sensors that utilize various optical phenomena.

However, there are only very few that are capable of simultaneously measuring multiple properties within an accumulator or battery.

In particular, simultaneous monitoring of the internal temperature and of the potential or of the state of lithiation of an accumulator electrode with a single sensor has never been achieved.

There is therefore a need to propose such a sensor that combines the measurement of temperature and the state of lithiation of an accumulator electrode.

The aim of the invention is to at least partly meet this need.

### DESCRIPTION OF THE INVENTION

To this end, one subject of the invention is a sensor for sensing temperature and measuring the state of charge (SOC) of an accumulator, in particular a metal-ion accumulator, comprising an optical fiber one free end of which forms an optical probe comprising one or more thermoluminescent materials capable of emitting a light peak at at least two wavelengths, at least one of the peaks being designed to be in at least one region of variation of the optical absorption spectrum of the metal ion insertion material of at least one electrode of the accumulator.

Advantageously, the wavelength of one of the two emission peaks is above 700 nm, preferably between 700 and 1100 nm, while that of the other of the two emission peaks is below 700 nm, preferably between 400 and 600 nm.

According to one variant embodiment, the optical probe comprises a matrix incorporating particles made of at least one thermoluminescent material.

Preferably, the thermoluminescent material is Er3+ and Yb3+-doped Gd2O2S or Y₂O₂S.

Another subject of the invention is a metal-ion accumulator (A) or battery, in particular a Li-ion accumulator or battery, comprising, inserted therein, at least one sensor as described above.

Multiple sensor installation variants may be envisaged:
the sensor may be in direct contact with the electrode whose state of lithiation varies;
the sensor may be in direct contact with that face of the separator of the accumulator opposite the one in contact with the electrode whose state of lithiation varies;
the sensor may be inserted into the separator or sandwiched between two separator layers of the accumulator.

Another subject of the invention is the use of a sensor as described above for measuring temperature at the same time as measuring the state of insertion of ions within a metal-ion accumulator, in particular the state of lithiation of a graphite negative electrode of a Li-ion accumulator.

The invention thus consists essentially of a fiber-optic temperature sensor carrying, at its end, an optical probe comprising one or more thermoluminescent materials having at least two emission peaks, that is to say two peaks in at least two different wavelengths, one of which lies in at least one region of variation of the optical absorption spectrum of the metal ion insertion material of at least one electrode of the accumulator, the ratio of the two peaks depending on the temperature of the accumulator and the variation in intensity of at least one of the two peaks being dependent on the insertion of the metal ions into the electrode.

By virtue of the invention, the same fiber-optic sensor whose probe is a thermoluminescence probe makes it possible both to measure the internal temperature of the accumulator and to measure, through luminescence absorption, the change in the insertion of ions, in particular lithiation of an electrode, in particular a graphite electrode, for a Li-ion accumulator, which is a method for estimating the state of charge (SOC) of the accumulator.

The operating principle of an optical-probe sensor according to the invention is as follows.

The probe comprising one or more thermoluminescent materials operates through ratiometry. The probe according to the invention has two transition peaks in the luminescence spectrum, which are used for the measurement. The first peak (peak 1) remains constant when the temperature changes, while the second peak (peak 2) decreases when the temperature increases (FIG. 10). There may be cases in which the first peak (peak 1) also varies, but in any case, it is the ratio of the two peaks that varies as a function of temperature, as explained in the preamble.

Once the probe has been positioned so as to interact optically with the electrode made of ion insertion material, such as graphite, the light that it will emit via the one or more luminescent materials will be absorbed by this electrode and this absorption will depend on the wavelength of the peak, but also on the insertion state, on the lithiation of the graphite in the case of a graphite negative electrode in a Li-ion accumulator. Therefore, considering that temperature does not vary and that the spectrum emitted by the probe as a function of the insertion state is measured, only the non-absorbed light is able to be measured, and this light depends on the insertion state, in particular the state of lithiation of the graphite.

FIG. 11 is a schematic view of the change of the luminescence spectrum measured as a function of the state of lithiation of the graphite of an electrode at constant temperature. As a function of the wavelength of the two peaks (peak 1, peak 2), their absorption by graphite as a function of its state of lithiation will not vary in the same proportion. By measuring the variation in intensity of one of the peaks (peak 1 or peak 2), or of the two peaks (peak 1, peak 2), it is thus possible to monitor the state of lithiation of the graphite, and therefore the state of charge (SOC) of a Li-ion accumulator.

That being the case, as explained in the preamble with reference to FIG. 6, temperature varies within an accumulator during cycling thereof and as a function of the current regime applied.

Therefore, by positioning a probe comprising one or more thermoluminescent materials in proximity to an accumulator electrode, in particular made of graphite, such that its luminescence is absorbed by the insertion material, such as graphite, the probe sensor makes it possible both to monitor the insertion state of the electrode material, in particular the lithiation of the graphite, and to measure the temperature within the accumulator.

As shown in FIG. 12, it is preferably possible to choose a peak (peak 3) within a range of high optical absorption of the electrode insertion material.

The insertion state (lithiation of graphite for a Li-ion accumulator with a graphite negative electrode) is then measured by monitoring the variation in intensity of one of the peaks (peak 1 or peak 2 or peak 3), or of the two peaks (peak 1, peak 2 or peak 3), whereas the temperature variation will be able to be measured based on the ratio of the two peaks

$$( \frac{Peak 2}{Peak 1} ) .$$

In order to optimize the operation of such a sensor for a Li-ion accumulator with a graphite negative electrode, one or more luminescent materials are preferably chosen with a luminescence peak (peak 3) that makes it possible to monitor the variation in the state of lithiation of graphite in a wavelength range above 700 nm, preferably between 700 and 1100 nm, the two peaks (peak 1, peak 2) or the reference peak (peak 1) in a wavelength range affected to a small extent by the optical absorption of graphite, preferably between 400 and 600 nm for the temperature measurement.

The chosen peak 3 is that of a material whose luminescence (that of peak 3) will not vary or will vary little as a function of temperature in the usual temperature variation range of an accumulator during operation.

Other advantages and features will emerge more clearly on reading the detailed description, which is given by way of non-limiting illustration, with reference to the figures below.

### BRIEF DESCRIPTION OF THE DRAWINGS

FIG. 1 is a schematic exploded perspective view showing the various elements of a lithium-ion accumulator.

FIG. 2 is a front view showing a lithium-ion accumulator with its flexible packaging according to the prior art.

FIG. 3 illustrates the luminescence spectrum of a thermoluminescent particle-based fiber-optic sensor whose two emission peaks change as a function of the temperature to which they are subjected.

FIG. 4 is the logarithmic line of response of the sensor according to FIG. 3.

FIG. 5 illustrates, at the bottom, the variation in the intensity of the luminescence signal of a luminescence sensor and the external temperature of a Li-ion accumulator of 1 A·h during electrochemical cycling (charging and discharging) to which it is subjected, characterized by the curves, at the top, of the variation in the voltage and the applied current.

FIG. 6 illustrates the variation in the internal temperature compared with the variation in the external temperature of a Li-ion accumulator of 1 A·h as a function of the electrochemical cycling to which it is subjected, characterized by the curves, at the top, of the variation in the voltage.

FIG. 7 is the reproduction of an image of the surface of a graphite anode of an accumulator as a function of its graphite state of lithiation and the state of charge of the anode.

FIG. 8 illustrates the variation in the graphite reflectance spectrum as a function of state of charge in a wavelength range measured by reflectance on an electrode alone (post mortem), outside installation in an accumulator.

FIG. 9 illustrates the variation in the transmittance spectrum (ΔT/T) as a function of the state of charge (capacity) of an accumulator, measured in-situ, in accordance with the prior art, by way of evanescent waves using an optical fiber.

FIG. 10 illustrates the variation in the spectrum of a thermoluminescent-probe sensor for the ratiometry-based temperature measurement of two emission peaks.

FIG. 11 illustrates the variation in intensity of the peaks of a thermoluminescent-probe sensor, measured as a function of the state of lithiation of graphite at constant temperature.

FIG. 12 illustrates the variation in spectra of a thermoluminescent-probe sensor according to the invention capable of simultaneously measuring temperature through luminescence ratiometry (peak 1 and peak 2) and variation in graphite lithiation (peak 3) through optical absorption.

FIG. 13 is a longitudinal sectional view of a thermoluminescent-probe fiber-optic measuring sensor according to the invention.

FIGS. 14A, 14B and 14C schematically show the optical probe of the sensor according to FIG. 13, when the measurement environment consisting of a Li-ion accumulator has respectively no impact on the measurement related to a change in optical absorption, an impact due to lithiation, and due to delithiation of the graphite negative electrode of the accumulator.

FIG. 14D illustrates the variation in intensity of the peaks of the thermoluminescent-probe sensor in an environment according to FIGS. 14B and 14C, measured as a function of the state of lithiation of graphite at constant temperature.

FIG. 14E illustrates the variation in spectra of the thermoluminescent-probe sensor according to the invention in an environment according to FIG. 14B or 14C, capable of simultaneously measuring temperature through luminescence ratiometry (peak 1 and peak 2) and variation in graphite lithiation (peak 3) through optical absorption.

FIG. 15 is the luminescence spectrum of Er³⁺ and Yb³⁺-doped Gd₂O₂S under light excitation at 980 nm.

FIG. 16 is the variation in the luminescence spectrum of Er3+ and Yb3+-doped Gd₂O₂S under light excitation at 980 nm, as a function of temperature.

FIGS. 17A, 17B and 17C illustrate various possible installation configurations for a sensor according to the invention within a Li-ion accumulator.

FIG. 18 is one example of the variation in the intensity of the peak S and of the intensity ratio of the peaks H and S of Er³⁺ and Yb³⁺-doped Gd₂O₂S, the spectrum of which is given in FIG. 16, during cycling of a Li-ion accumulator with a graphite negative electrode.

FIG. 19 is one example of a measurement for a 4 C discharge of a Li-ion accumulator with a graphite negative electrode showing the variation in temperature, the variation in the intensity of the peak H and that of the peak S and their ratio obtained with a probe comprising Er³⁺ and Yb³⁺-doped Gd₂O₂S material, the spectrum of which is given in FIG. 16.

FIG. 20 is the result of the data processing for extracting the contribution due to the optical absorption of graphite of a negative electrode of a Li-ion accumulator during the 4 C discharge in order to deduce therefrom the variation on the variation in the intensity of the peak H and on the variation in the intensity of the peak S.

FIG. 21 is the result of the data processing for extracting the contribution due to the optical absorption of graphite of a negative electrode of a Li-ion accumulator during the 4 C discharge in order to deduce therefrom the variation on the variation in the intensity of the peak S.

FIG. 22 is the correlation between the external temperature measured by a thermocouple, the variation in the ratio of the peaks H and S and the temperature measured by a thermoluminescence sensor according to the invention after removing the contribution of graphite from the signal.

### DETAILED DESCRIPTION

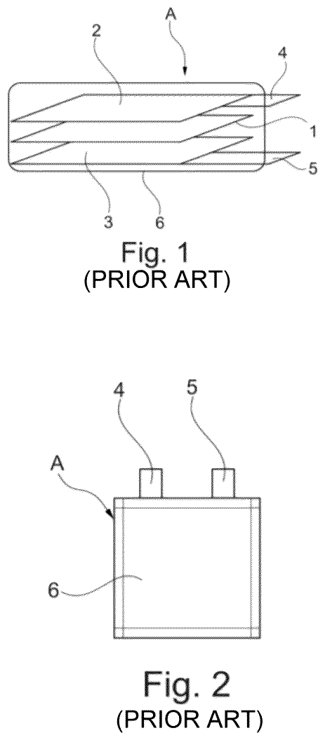

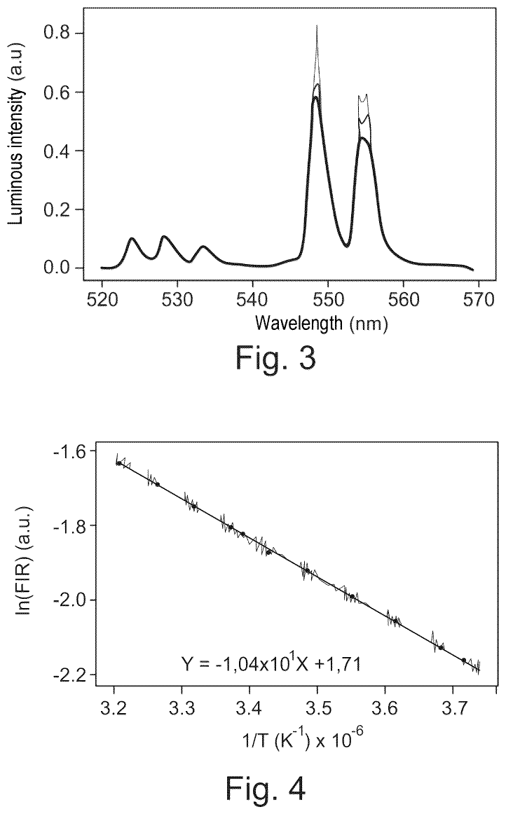

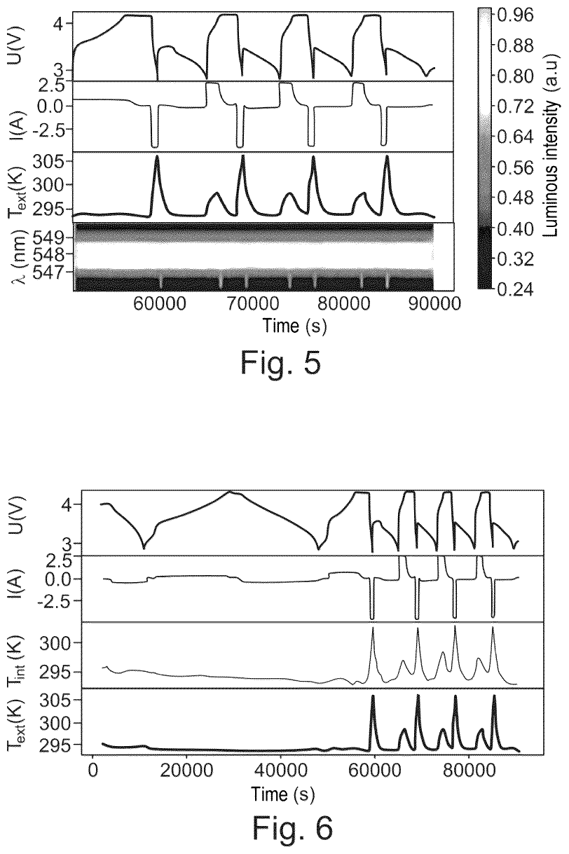

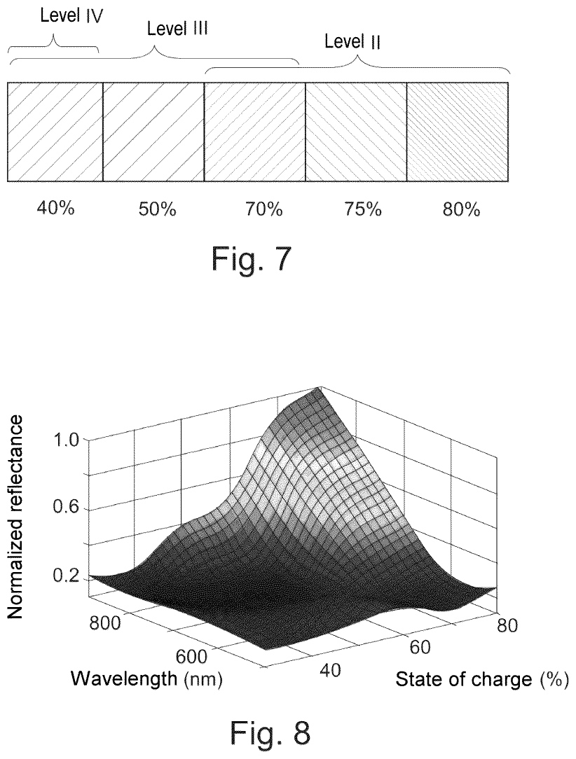

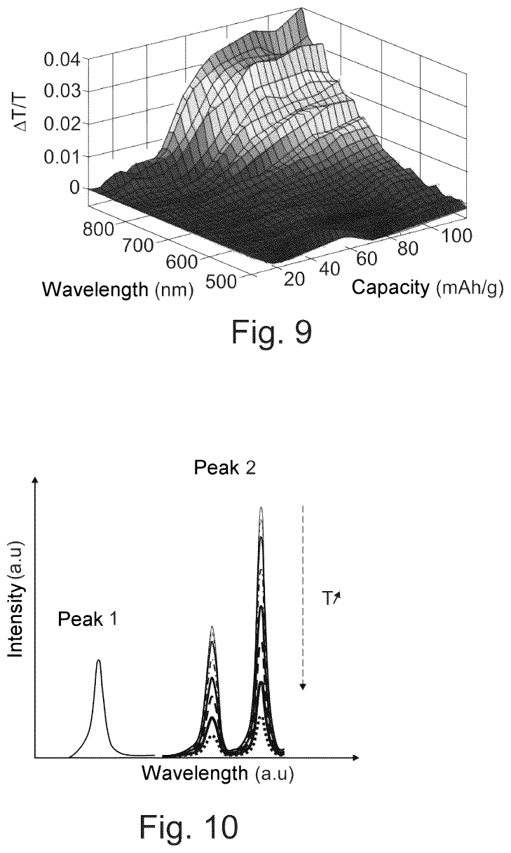

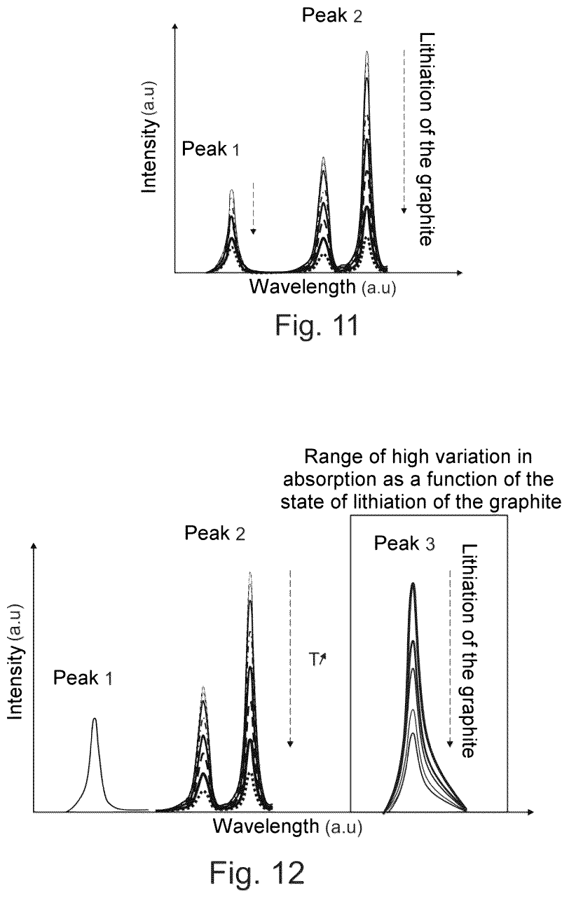

FIGS. 1 to 12 have already been described in the preamble. They will therefore not be detailed below.

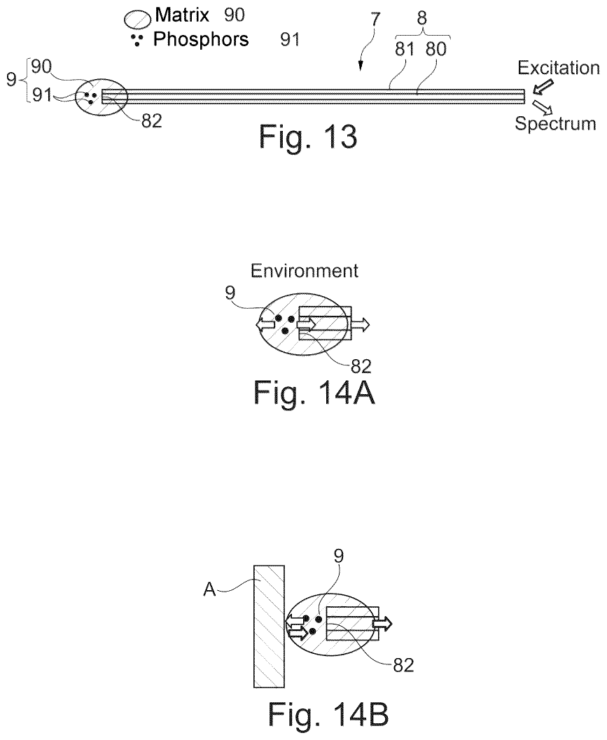

FIG. 13 shows a fiber-optic measuring sensor 7 according to the invention.

It comprises an optical fiber 8 consisting of a core 80 designed to propagate light and a sheath 81 surrounding the core.

A free end 82 of the fiber carries an optical probe 9 consisting of a matrix 90 comprising thermoluminescent particles, also called phosphors 91.

The matrix 30 may be a silica sol-gel, a polymer or any other organic or hybrid material transparent in the wavelength ranges used and capable of withstanding the environment of the electrolyte of a metal-ion accumulator in which the optical fiber 2 and the optical probe 3 are immersed. Examples of materials for the matrix 30, deposited in particular by sol-gel deposition, are as described in patent application EP4155700A1. The matrix may also be made of polymethyl methacrylate (PMMA).

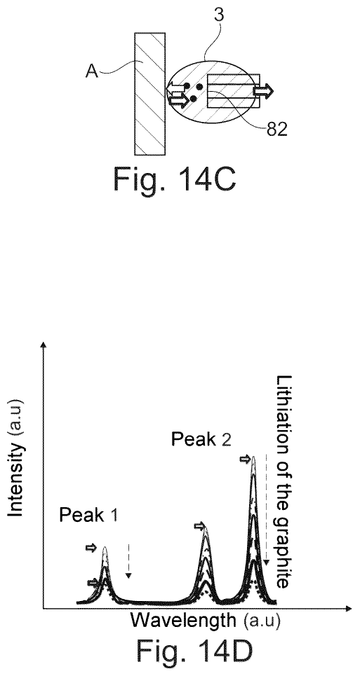

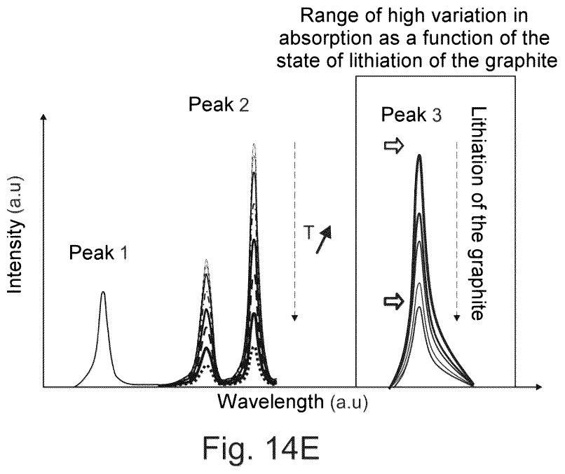

The various FIGS. 14A to 14C show various configurations in which the sensor 7 according to the invention operates.

To probe the phosphors 91, excitation light whose wavelength depends on the type of phosphors used is sent by the core 80 of the fiber.

The phosphors that are then excited emit light whose emission spectrum with peaks is characteristic of the nature of the phosphor.

If the optical probe 9 of the sensor 7 is outside or in an environment without an optical impact, then the luminescence spectrum of the probe 9 is emitted in all directions and a portion returns to the optical fiber without being modified by the environment (FIG. 14A).

When the optical probe 9 is positioned within a Li-ion accumulator, so as to interact optically with the graphite of the electrode, the state of lithiation thereof will modify the luminescence spectrum that is recovered by the optical fiber 8 since a portion thereof will be absorbed by the graphite (FIGS. 14B and 14C).

This absorption difference is then measured by spectral measurement, as illustrated in FIGS. 14D and 14E. It is also possible to measure this optical absorption difference by way of photodetectors centered on the peaks of interest, peak 1, peak 2, peak 3.

The phosphors 91 may be made of a single thermoluminescent material whose luminescence spectrum comprises multiple peaks, some of which are dedicated to measuring temperature and others of which are dedicated to measuring the state of lithiation of the graphite.

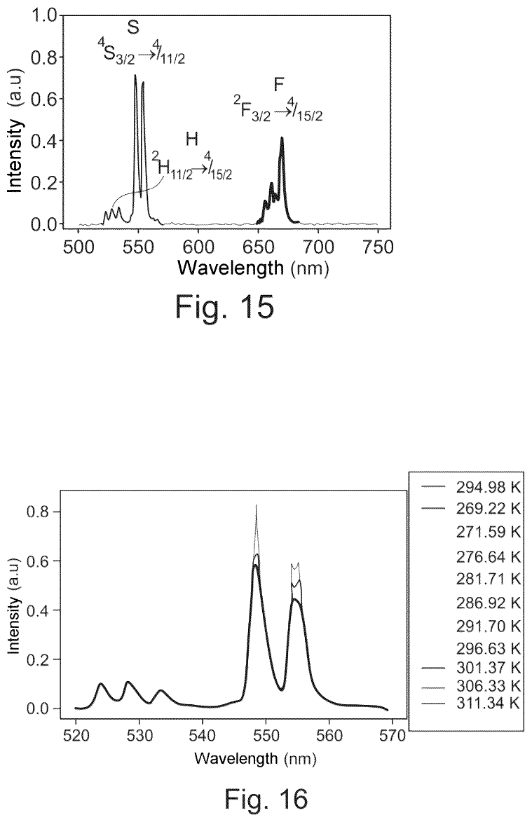

Er³⁺ and Yb³⁺-doped Gd₂O₂S or Y₂O₂S or NaYF₄ or NaGdF₄ or YVO₄ are ideal materials that are able to be excited at a wavelength of 980 or 1500 nm. The luminescence spectrum of Er³⁺. Yb³⁺-doped Gd₂O₂S, excited at 980 nm, is shown in FIG. 15: the three peaks correspond to the transitions called H, S and F. The peaks or transitions S and H are thermally coupled and make it possible, through ratiometry, to find out the temperature.

FIG. 16 illustrates the variation in the luminescence spectrum of Er³⁺, Yb³⁺-doped Gd₂O₂S under excitation at 980 nm as a function of temperature.

The sensor 7 according to the invention has the primary advantage of being able to be inserted at a single point of a Li-ion accumulator for which it is sought to measure the state of lithiation of the negative electrode.

The probe 9 of the sensor may thus be placed facing the graphite negative electrode, inserted into it or else on the other side of the separator of the accumulator, provided that the latter is optically transparent in the wavelengths of interest for monitoring the lithiation of the graphite. This is for example the case for a polymer porous separator conventionally used in Li-ion accumulators, such as Celgard®. Such a separator impregnated with electrolyte is transparent and the probe 9 of the sensor is therefore able to measure the state of lithiation of the graphite electrode underneath, even with the separator arranged between the two.

When the separator of the accumulator is transparent in the wavelength range of interest for monitoring the lithiation of the graphite, it is also possible to place the sensor 7 in the thickness of the separator or else between two successive separator layers.

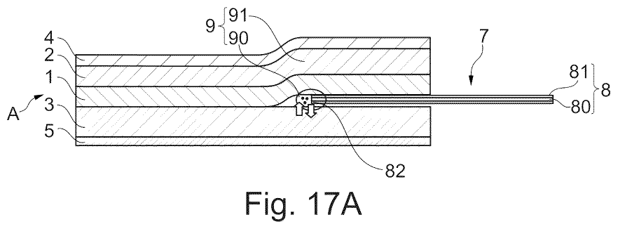

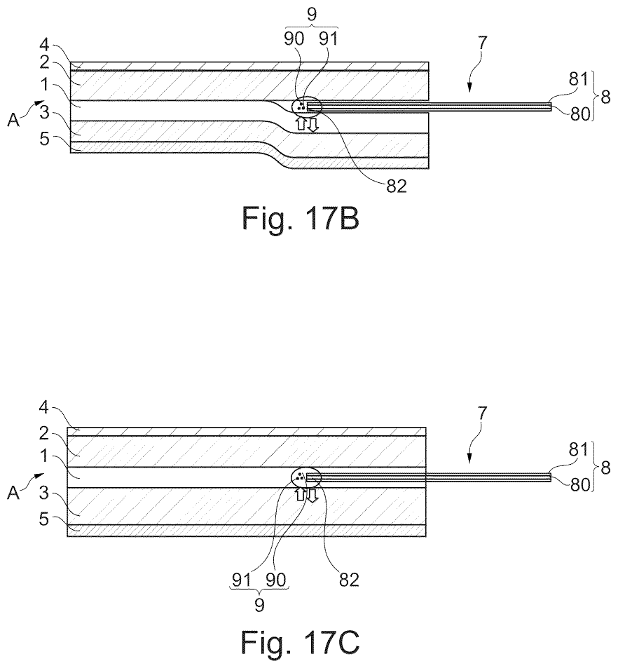

FIGS. 17A, 17B and 17C show various installation configurations, respectively as follows:
the sensor 7 is in direct contact with the graphite electrode 3,
the sensor 7 is in direct contact with that face of the separator 1 opposite the one in contact with the graphite electrode 3,
the sensor 7 is inserted into the separator or sandwiched between two separator layers.

As already mentioned, the configurations in FIGS. 17B and 17C assume that the separator 1 is transparent in the wavelength range used to monitor the absorption of graphite.

The inventors carried out tests on a Li-ion accumulator, comprising a flexible packaging (“pouch”), consisting of a graphite negative electrode, an NMC622 positive electrode and a Celgard Separator® without coating.

The sensor 7 that is implemented has a matrix 90 as described in patent application EP4155700A1 incorporating, as phosphors 91, particles of Er3+ and Yb3+-doped Gd₂O₂S sold under the reference PTIR545UF by Phosphor Technology, whose luminescence spectrum under excitation at 980 nm is given in FIG. 15.

This optical probe was positioned within the Li-ion accumulator.

The temperature was measured by determining the ratio of the two emission peaks H and S. As already mentioned, the peak H remains constant whatever the temperature, whereas the peak S decreases when the temperature increases (FIG. 16).

The inventors subjected the accumulator to electrochemical cycling of charging and discharging at a slow regime.

In this regime, the temperature of the accumulator does not increase.

Next, the accumulator was subjected to a 4 C discharge, which led to an increase in the temperature of the accumulator of around 10° C.

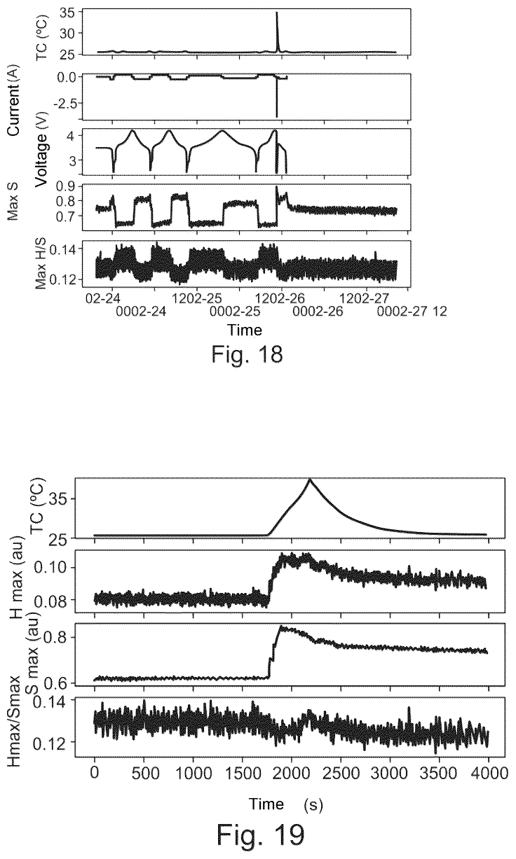

The results of these measurements are illustrated in FIGS. 18 and 19.

FIG. 18 shows the curves of variation in the intensity of the peak S and of the intensity ratio between the peaks H and S during cycling at a slow regime.

It may be seen that the ratio varies as a function of the charging or discharging phase of the accumulator (current plateaus) for low regimes. It may also be seen that the shape of the intensity of the peak S depends on the charging or discharging regime and on the intensity of the current.

In other words, when the accumulator is subjected to cycling at a slow regime and the temperature does not change, the response of the optical sensor indeed changes as a function of the cycling. This change corresponds to a variation in the optical absorption within the cell and is correlated with the variation in lithiation of the graphite.

FIG. 19 illustrates, for a 4 C discharge, the variation in the temperature, the variation in the intensity of H and that of S, and the ratio between the peaks S and H.

It may be seen that the two effects are coupled, and the effect of the lithiation of the graphite during discharge on the intensity of the peaks H and S is clearly visible (increase and then relaxation). The effect of temperature is visible, but to a lesser extent on the ratio.

By extracting the contribution of the absorption due to lithiation of the graphite on the signal of the peaks H and S, it is possible to extract the contribution of the signal due to temperature. For this purpose, it is considered that the intensity of the peak H must remain constant. The contribution due to absorption by the graphite is then deduced therefrom as a difference.

This then makes it possible to correct the variation in the peak S. This processing makes it possible to extract the variation in the ratio between the peaks S and H related to temperature.

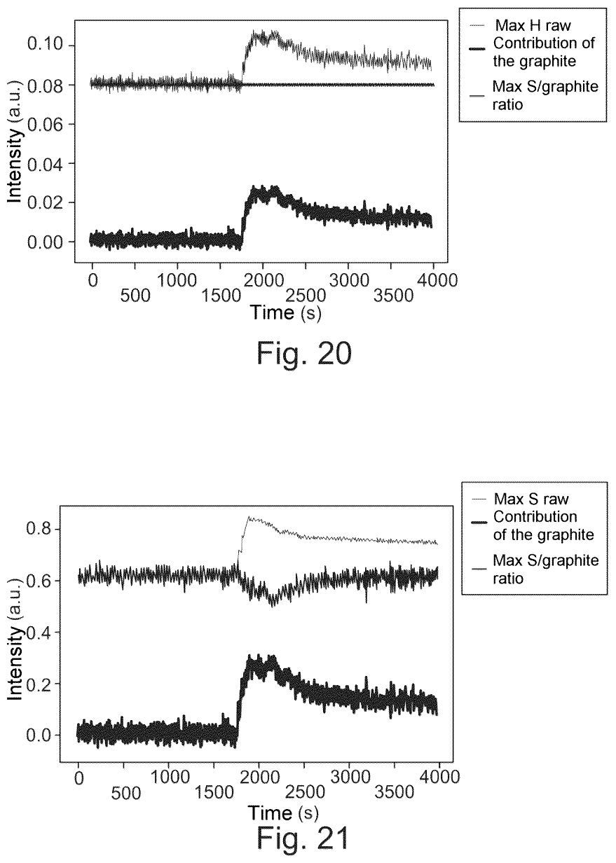

FIG. 20 illustrates the variation in the intensity of the peak H during the 4 C discharge.

FIG. 21, for its part, illustrates the variation in the intensity of the peak S during this same discharge.

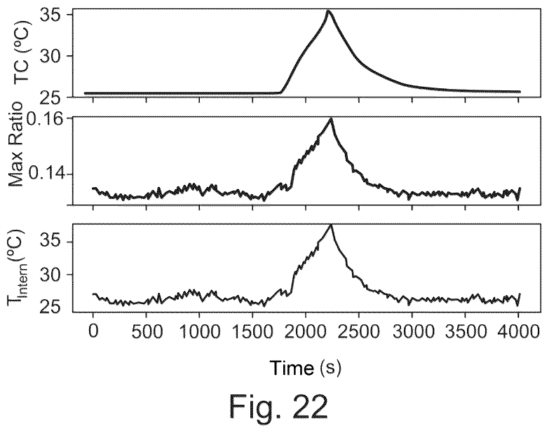

After this data processing, it is possible to establish a correlation between the external temperature Tₑₓₜ of the accumulator measured by thermocouple, the variation in the ratio of intensity of the peaks H and S after correcting the contribution of the absorption of the graphite, and the internal temperature Tᵢₙₜ calculated based on the calibration curve of the thermoluminescence sensor, as illustrated in FIG. 22.

Further variants and improvements may be envisaged without exceeding the scope of the invention.

The sensor 7 according to the example illustrated is implemented in accordance with techniques, in particular by sol-gel according to patent application EP4155700A1. The invention may be applied to any other type of optical thermoluminescence probe using another type of particles or molecules as phosphors and another type of material for the matrix with at least two emission peaks, one of which is constant at the temperature and the other of which is in a region of optical absorption, preferably in a region of high variation thereof depending on the state of lithiation, more generally on the insertion state of an electrode insertion material in a metal-ion accumulator.

Thus, although the invention has been described in relation to a graphite negative electrode, the sensor according to the invention may very well be implemented in a metal-ion accumulator with another chemistry of the anode or cathode materials insofar as these one or more materials exhibit an optical absorption that changes with its state of charge and if this change is able to be measured in the same way without disturbing the thermoluminescence temperature measurement.

To implement the sensor, it is possible to envisage other materials referred to as “up-converter” materials that have thermoluminescence properties.

### LIST OF CITED REFERENCES

[1]: https://battery2030.eu/research/roadmap/
[2]: https://www.instabat.eu/
[3]: Wang, R., Zhang, H., Liu, Q., Liu, F., Han, X., Liu, X., Li, K., Xiao, G., Albert, J., Lu, X. & Guo, T. “Operando monitoring of ion activities in aqueous batteries with plasmonic fiber-optic sensors” Nature Communications 13, 547 (2022).
[4]: Lu, X., Tarascon, J.-M. & Huang, J. “Perspective on commercializing smart sensing for batteries”. eTransportation 14, 100207 (2022). Wang, R., Zhang, H., Liu, Q., Liu, F., Han.
[5]: Hedman, J., Mogensen, R., Younesi, R. & Björefors, F. “Fiber Optic Sensors for Detection of Sodium Plating in Sodium-Ion Batteries”. ACS Applied Energy Materials (2022) doi: 10.1021/acsaem.2c00595.
[6]: Ghannoum, A., Norris, R. C., Iyer, K., Zdravkova, L., Yu, A. & Nieva, P. “Optical Characterization of Commercial Lithiated Graphite Battery Electrodes and in Situ Fiber Optic Evanescent Wave Spectroscopy.” ACS Applied Materials and Interfaces 8, 18763-18769 (2016).
[7]: Ghannoum, A., Iyer, K., Nieva, P. & Khajepour, A. “Fiber optic monitoring of lithium-ion batteries: A novel tool to understand the lithiation of batteries”. in Proceedings of IEEE Sensors (2017). doi: 10.1109/ICSENS.2016.7808695.
[8]: Ghannoum, A., Nieva, P., Yu, A. & Khajepour, A. “Development of Embedded Fiber-Optic Evanescent Wave Sensors for Optical Characterization of Graphite Anodes in Lithium-Ion Batteries.” ACS Appl. Mater. Interfaces 9, 41284-41290 (2017).
[9]: Ghannoum, A. & Nieva, P. “Graphite lithiation and capacity fade monitoring of lithium ion batteries using optical fibers.” Journal of Energy Storage 28, 101233 (2020)
[10]: Modrzynski, C., Roscher, V., Rittweger, F., Ghannoum, A., Nieva, P. & Riemschneider, K. “Integrated Optical Fibers for Simultaneous Monitoring of the Anode and the Cathode in Lithium Ion Batteries.” in 2019 IEEE SENSORS 1-4 (2019). doi: 10.1109/SENSORS43011.2019.8956755.

1. A sensor for sensing temperature and measuring the state of charge (SOC) of an accumulator, in particular a metal-ion accumulator, comprising an optical fiber one free end of which forms an optical probe comprising one or more thermoluminescent materials capable of emitting a light peak at at least two wavelengths, at least one of the two peaks being designed to be in at least one region of variation of the optical absorption spectrum of the metal ion insertion material of at least one electrode of the accumulator, the ratio of the two peaks depending on the temperature of the accumulator and the variation in intensity of at least one of the two peaks being dependent on the insertion of the metal ions into the electrode.

2. The sensor as claimed in claim 1, the wavelength of one of the two emission peaks being above 700 nm while that of the other of the two emission peaks is below 700 nm.

3. The sensor as claimed in claim 1, the optical probe comprising a matrix incorporating particles made of at least one thermoluminescent material.

4. The sensor as claimed in claim 1, the thermoluminescent material being Er3+ and Yb3+-doped Gd2O2S or Y₂O₂S.

5. A metal-ion accumulator (A) or battery, in particular a Li-ion accumulator or battery, comprising, inserted therein, at least one sensor as claimed in claim 1.

6. The accumulator as claimed in claim 5, the sensor being in direct contact with the electrode whose state of lithiation varies.

7. The accumulator as claimed in claim 5, the sensor being in direct contact with that face of the separator of the accumulator opposite the one in contact with the electrode whose state of lithiation varies.

8. The accumulator as claimed in claim 5, the sensor being inserted into the separator or sandwiched between two separator layers of the accumulator.

9. The use of a sensor as claimed in one of claim 1 for measuring temperature at the same time as measuring the state of insertion of ions within a metal-ion accumulator, in particular the state of lithiation of a graphite negative electrode of a Li-ion accumulator.

10. The sensor as claimed in claim 1, the wavelength of one of the two emission peaks is between 700 and 1100 nm while the other of the two emissions peaks is between 400 and 600 nm.

11. The sensor as claimed in claim 2, the optical probe comprising a matrix incorporating particles made of at least one thermoluminescent material.
